(19) United States
(12) Patent Application Publication
(10) Pub. No.: US 2021/0408198 A1
(43) Pub. Date: Dec. 30, 2021

(54) Chip Structure and Display Device

(71) Applicant: Wuhan China Star Optoelectronics Semiconductor Display Technology Co., LTD., Wuhan, Hubei (CN)

(72) Inventors: Juan LIU, Wuhan, Hubei (CN); Yu LIU, Wuhan, Hubei (CN)

(73) Assignee: Wuhan China Star Optoelectronics Semiconductor Display Technology Co., LTD., Wuhan, Hubei (CN)

(21) Appl. No.: 16/485,429

(22) PCT Filed: Apr. 25, 2019
(86) PCT No.: PCT/CN2019/084180

§ 371 Date: Aug. 12, 2019

(30) Foreign Application Priority Data
Dec. 24, 2018 (CN) 201811583628.3

(51) Int. Cl. H01L 27/32

(52) U.S. Cl. CPC H01L 27/3276; H01L 27/326; H01L 27/3255

(57) ABSTRACT

A chip structure includes a chip substrate and a plurality of bumps. The plurality of bumps are disposed on a surface of the chip substrate and function as an interface for electrical connection between the chip substrate and an external connecting portion. The plurality of bumps are spaced apart from each other, and each of the plurality of bumps includes a rhombic configuration.

### BACKGROUND OF INVENTION

### 1. Field of Invention

The present invention relates to a technical field of displays, and particularly, to a chip structure and a display device.

### 2. Related Art

With advancement of display technology, flat panel display technology has long been used by mainstream display devices. Particularly, organic light-emitting diodes (OLEDs) have become display devices having most potential in recent years, due to advantages of being self-luminous, all-solid, and high contrast, etc. In organic light-emitting diode display devices, a driver chip is usually provided to control each pixel.

In addition, as resolution increases to four times the wide quad high definition (WQHD) or even ultra high definition (UHD), bonding pads of chips are configured with fine pitches, getting smaller and smaller and reaching a micron level, and requirements for bonding are getting higher and higher. Chip bonding is usually performed by bonding chips with panels through electrically conductive films, thereby to realize upper and lower electrically conduction through electrically conductive particles of the electrically conductive films. In a situation of certain shifting, number of electrically conductive particles in overlapping parts of chips and electrically conductive films and the panels needs to be greater than a certain number to ensure electrically conduction performance. It is also necessary to prevent a short circuit between left and right electrodes from being caused by accumulation of the electrically conductive particles. Electrodes (also known as contact bumps) on surfaces of conventional chips are mostly I-shaped, but pitches between the I-type electrodes are small, so flowability of the electrically conductive particles is poor. Besides, it is easy to cause short circuit due to the accumulation of electrically conductive particles. Furthermore, when chips are shifting, an overlapping area of the I-type electrodes and the panel is reduced, and thus number of effective electrically conductive particles becomes small that is easy to result in poor bonding. Still further, distribution of contact bumps of traditional chips is longer in Y axis, limiting design for electrode sizes, and unbeneficial to design of small electrodes, thereby failing to improve electrically conduction performance by contact. The drawbacks caused by a structure of transitional chip electrodes as described above seriously adversely affect bonding performance of chips, and further cause circuits to be short-circuited giving rise to abnormal display of display devices.

### SUMMARY OF INVENTION

Accordingly, an object of the present invention is to provide a chip structure and a display device, capable of allowing electrically conductive particles of an electrically conductive film for adhering the chip structure to flow smoothly between chip electrodes when boning the chip structure, thereby increasing a capture rate of the electrically conductive particles, improving reliability of bonding, and avoiding short circuits.

To achieve the above-mention object, the present invention provides a chip structure, comprising a chip substrate; and a plurality of bumps disposed on a surface of the chip substrate and functioning as an interface for electrical connection between the chip substrate and an external connecting portion, wherein the plurality of bumps are spaced apart from each other, each of the plurality of bumps comprises a rhombic configuration with four sides of equal length, and at least one of the four sides is disposed at an angle of 45 degrees with respect to a horizontal line passing through an end point of the at least one of the four sides; wherein the plurality of bumps are arranged in rows in a transverse direction, and are arranged in columns in a longitudinal direction, and wherein the plurality of bumps in rows in the transverse direction are disposed in a staggered manner, and the plurality of bumps in columns in the longitudinal direction are disposed in a staggered manner.

The present invention further provides a chip structure, comprising a chip substrate; and a plurality of bumps disposed on a surface of the chip substrate and functioning as an interface for electrical connection between the chip substrate and an external connecting portion, wherein the plurality of bumps are spaced apart from each other, and each of the plurality of bumps comprises a rhombic configuration.

In a preferable embodiment of the present invention, each of the plurality of bumps has four sides of equal length, and at least one of the four sides is disposed at an angle of 45 degrees with respect to a horizontal line passing through an end point of the at least one of the four sides.

In another preferable embodiment of the present invention, the plurality of bumps are arranged in rows in a transverse direction, and are arranged in columns in a longitudinal direction, and wherein the plurality of bumps in rows in the transverse direction are disposed in a staggered manner, and the plurality of bumps in columns in the longitudinal direction are disposed in a staggered manner.

In another preferable embodiment of the present invention, each of the plurality of bumps in rows in the transverse direction is arranged at an equal pitch, and each of the plurality of bumps in columns in the longitudinal direction is arranged at an equal pitch.

In another preferable embodiment of the present invention, the chip substrate is bonded to the external connecting portion by an electrically conductive film, a shifting distance is formed between the chip substrate and the external connecting portion, and wherein the plurality of bumps in each row are in alignment with each other in the transverse direction, and a pitch is formed between the bumps adjacent to each other in the same row in the transverse direction and the pitch is greater than or equal to the shifting distance.

In another preferable embodiment of the present invention, the surface of the chip substrate is rectangular in shape and has a first side and a second side perpendicular to the first side, and wherein each of the plurality of bumps having the rhombic configuration comprises a first corner connecting line perpendicular to the first side, and a second corner connecting line perpendicular to the first corner connecting line and the second side.

The present invention further provides a display device, comprising an organic light emitting display panel, a bonding area, and a chip structure disposed on the bonding area, wherein the chip structure comprises a chip substrate; and a plurality of bumps disposed on a surface of the chip substrate and functioning as an interface for electrical connection between the chip substrate and an external connecting portion, wherein the plurality of bumps are spaced apart from each other, and each of the plurality of bumps comprises a rhombic configuration.

In a preferable embodiment of the present invention, each of the plurality of bumps has four sides of equal length, and at least one of the four sides is disposed at an angle of 45 degrees with respect to a horizontal line passing through an end point of the at least one of the four sides.

In another preferable embodiment of the present invention, the plurality of bumps are arranged in rows in a transverse direction, and are arranged in columns in a longitudinal direction, and wherein the plurality of bumps in rows in the transverse direction are disposed in a staggered manner, and the plurality of bumps in columns in the longitudinal direction are disposed in a staggered manner.

In another preferable embodiment of the present invention, the chip substrate is bonded to the bonding area by an electrically conductive film, a shifting distance is formed between the chip substrate and the external connecting portion, and wherein the plurality of bumps in each row are in alignment with each other in the transverse direction, and a pitch is formed between the bumps adjacent to each other in the same row in the transverse direction and the pitch is greater than or equal to the shifting distance.

The chip structure of the present invention utilizes the rhombic bumps to effectively enhance flowability of the electrically conductive particles of the electrically conductive film when bonding chips, thereby increasing a capture rate of the electrically conductive particles, reducing accumulation of the electrically conductive particles, avoiding short circuits, and further ensuring a normal operation of a display device. The chip structure 1 of the present invention effectively overcome drawbacks that flowing of electrically conductive particles between bump electrodes of a chip tends to be blocked, thereby giving rise to short circuits easily, and unbeneficial to development of small-sized chips

### BRIEF DESCRIPTION OF DRAWINGS

FIG. 1 is a schematic side view showing bonding of a chip structure of a preferable embodiment of the present invention.

FIG. 2 is a schematic view showing a chip structure of a preferable embodiment of the present invention.

FIG. 3 is a schematic view showing part of a chip structure of a preferable embodiment of the present invention.

FIG. 4 is a schematic view of a chip structure of a preferable embodiment of the present invention, for showing a difference in a bonding area of a chip structure after the chip structure is shifting.

FIG. 5 is a schematic view of a display device of a preferable embodiment of the present invention.

### DESCRIPTION OF PREFERRED EMBODIMENTS

The following embodiments are referring to the accompanying drawings for exemplifying specific implementable embodiments of the present invention. Directional terms described by the present invention, such as upper, lower, front, back, left, right, inner, outer, side, etc., are only directions by referring to the accompanying drawings, and thus the used directional terms are used to describe and understand the present invention, but the present invention is not limited thereto.

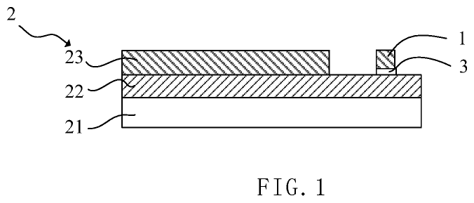

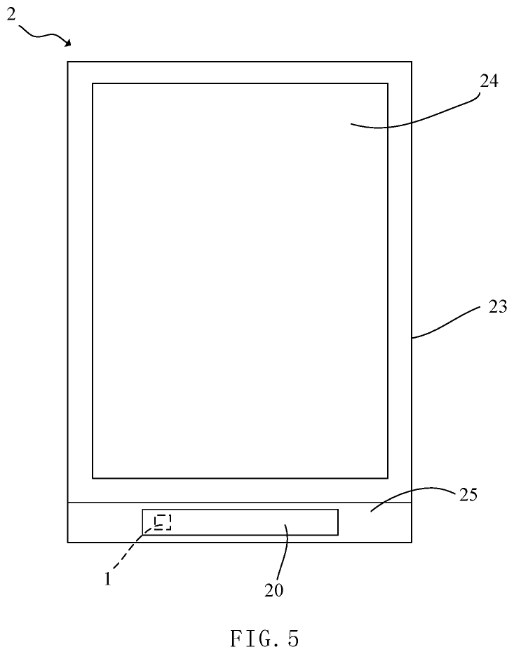

The present invention is a chip structure, which may be a driver chip (also referred to IC) for controlling each pixel, and is adapted to a display device, wherein the display device may be a liquid crystal display panel or an organic light emitting display panel. FIG. 1 is a schematic side view showing bonding of a chip structure of a preferable embodiment of the present invention. As shown in FIG. 1, the chip structure 1 is adapted to a display device 2. The display device 2 includes a glass substrate 21, an organic film layer 22 disposed on the glass substrate 21, and a bonding area 20 (as shown in FIG. 5) and an organic light-emitting diode (OLED) panel 23 disposed on the organic film layer 22. Specifically, the chip structure 1 is bonded to the bonding area 20 by an electrically conductive film 3. In this preferable embodiment, the electrically conductive film 3 is an anisotropic conductive film (ACF).

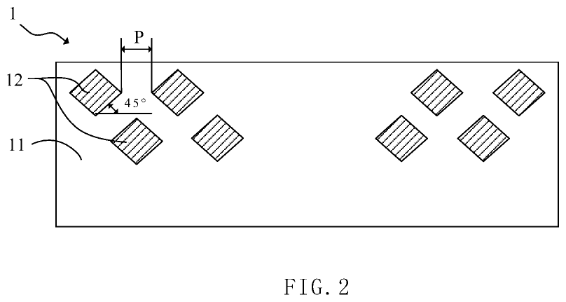

FIG. 2 is a schematic view showing a chip structure of a preferable embodiment of the present invention. The chip structure 1 of the present invention includes a chip substrate 11 and a plurality of bumps 12 disposed on a surface of the chip substrate 11. The plurality of bumps 12 function as an interface for electrical connection between the chip substrate 11 and the OLED panel 23; that is, the plurality of bumps 12 also function as electrodes. The plurality of bumps 12 are spaced apart from each other, and a cross section of each of the bumps 12 parallel with the surface of the chip substrate 11 includes a rhombic configuration. Particularly, in this preferable embodiment, each of the bumps 12 has four sides of equal length, wherein each of the four sides is disposed at an angle of 45 degrees with respect to a horizontal line. Specifically, at least one of the four sides of each bump is disposed at an angle of 45 degrees with respect to a horizontal line passing through an end point of the at least one of the four sides. Furthermore, the plurality of bumps 12 are arranged in rows in a transverse direction, and are arranged in columns in a longitudinal direction, and wherein the plurality of bumps 12 in rows in the transverse direction are disposed in a staggered manner, and the plurality of bumps 12 in columns in the longitudinal direction are disposed in a staggered manner. In another embodiment, each of the plurality of bumps 12 in rows in the transverse direction is arranged at an equal pitch, and each of the plurality of bumps 12 in columns in the longitudinal direction is arranged at an equal pitch, but not limited thereto.

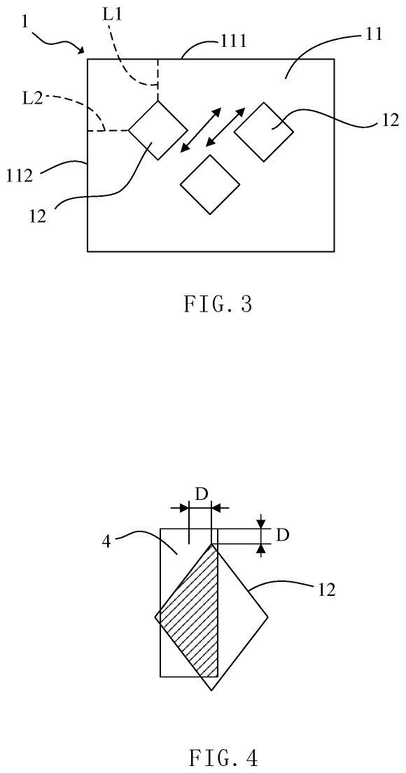

FIG. 3 is a schematic view showing part of a chip structure of a preferable embodiment of the present invention. As described above, the chip structure 1 is bonded by the electrically conductive film 3 (i.e. ACF). Because the plurality of bumps 12 of the present invention are rhombic in shape and are arranged in staggered relationship to each other, an area between the bumps 12 adjacent to each other is a parallelogram in shape, thereby forming a channel beneficial for electrically conductive particles of the ACF not to be blocked when flowing, thereby avoiding short circuits caused by accumulation of the electrically conductive particles of the ACF and improving reliability of bonding. Furthermore, the surface of the chip substrate 11 is rectangular in shape and has a first side 111 and a second side 112 perpendicular to the first side 111. Each of the plurality of bumps 12 has the rhombic configuration includes a first corner connecting line L1 perpendicular to the first side 111, and a second corner connecting line L2 perpendicular to the first corner connecting line L1 and the second side 112. By an arrangement relationship between the rhombic bumps 12 and the chip substrate 11, it is also beneficial for the electrically conductive particles of the ACF not to be blocked when the electrically conductive particles are flowing.

Please continue referring to FIGS. 2 and 3. Generally, when a chip is being bonded, a shifting distance D (as shown in FIG. 4) is more or less formed between the chip substrate and the bonding area of the external connecting portion, wherein a shifting distance occurred in bonding ICs is generally less than or equal to five microns in a direction of X-axis and Y-axis. Particularly, consider that a difference in an overlapping area of a chip contact bump and an external connecting portion will be caused by the above-mentioned shifting distance, the plurality of bumps 12 in each row are in alignment with each other in the transverse direction, and a pitch P is formed between the bumps 12 adjacent to each other in the same row in the transverse direction, wherein the pitch P is greater than or equal to the shifting distance D. That is, the pitch P formed between the bumps 12 adjacent to each other in the same row in the transverse direction is greater than or equal to five microns. The plurality of rhombic bumps 12 are arranged at the pitch P to allow the electrically conductive particles of the ACF to flow smoothly, thereby not only strengthening bonding of the chip substrate 11, but also ensuring electrical connection of the chip substrate 11 and the bonding area 20.

FIG. 4 is a schematic view of a chip structure of a preferable embodiment of the present invention, for showing a difference in a bonding area of a chip structure after the chip structure is shifting. Compared with a conventional I-pillar type electrode 4 being rectangular in shape, since the plurality of bumps 12 of the present invention each have a rhombic shape and under a condition that the shifting distance D is equal, an area that each of the rhombic bumps 12 overlaps with a connecting portion of the bonding area 20 after the bump 12 is bonded is greater than that of the conventional I-pillar type electrode 4. In this manner, it is beneficial for the bumps of the present invention to capture more electrically conductive particles, thereby increasing electrically conductive performance. Specifically, each of the bumps 12 is configured with a contact area between 500 to 1500 microns. Furthermore, the rhombic bumps 12 are more beneficial to shorten a length of distribution of electrodes in the Y-axis, so that the bumps are distributed in a smaller range, thereby to follow a trend of small-sized chips.

Accordingly, the chip structure 1 of the present invention utilizes the rhombic bumps 12 to effectively enhance flowability of the electrically conductive particles of the ACF when bonding chips, thereby increasing a capture rate of the electrically conductive particles, reducing accumulation of the electrically conductive particles, avoiding short circuits, and further ensuring a normal operation of a display device. The chip structure 1 of the present invention effectively overcome drawbacks that flowing of electrically conductive particles between bump electrodes of a chip tends to be blocked, thereby giving rise to short circuits easily, and unbeneficial to development of small-sized chips.

FIG. 5 is a schematic view of a display device of a preferable embodiment of the present invention. Please refer to FIG. 5 in combination with FIG. 1. The present invention further provides a display device 2 including a bonding area 20, a chip structure 1 disposed on the bonding area 20, and an organic light emitting display panel 23. As shown in FIG. 5, the organic light emitting display panel 23 includes a display area 24 and a non-display area 25 disposed at peripheral edges of the display area 24, and the bonding area 20 is located at the non-display area 25.

The chip structure 1 includes a chip substrate 11 and a plurality of bumps 12 disposed on a surface of the chip substrate 11 and functioning as an interface for electrical connection between the chip substrate 11 and the bonding area 20 (i.e. an external connecting portion). The plurality of bumps 12 are spaced apart from each other, and each of the plurality of bumps 12 includes a rhombic configuration. Other detailed constructions relating to the chip structure 1 of the present invention have been described in detail in the foregoing description of the embodiment of FIGS. 1 to 4 and will not be repeated herein.

In another embodiment, the display device 2 of the present invention further includes a flexible circuit board (not shown) of which one end is electrically connected to the chip substrate of the chip structure. Another end of the flexible circuit board is electrically connected to an electronic main board of a display apparatus (not shown), such as mobile phones. The flexible circuit board transmits a control command and a power supply voltage from the electronic device main board to the chip structure, so that the chip structure provides voltage and data signals to the organic light-emitting diode panel 23, thereby making the display area 24 of the organic light-emitting diode panel 23 displays a desired picture (as shown in FIG. 5).

Accordingly, although the present invention has been disclosed as a preferred embodiment, it is not intended to limit the present invention. Those skilled in the art without departing from the spirit and scope of the present invention may make various changes or modifications, and thus the scope of the present invention should be after the appended claims and their equivalents.

What is claimed is:

1. A chip structure, comprising:
a chip substrate; and
a plurality of bumps disposed on a surface of the chip substrate and functioning as an interface for electrical connection between the chip substrate and an external connecting portion, wherein the plurality of bumps are spaced apart from each other, each of the plurality of bumps comprises a rhombic configuration with four sides of equal length, and at least one of the four sides is disposed at an angle of 45 degrees with respect to a horizontal line passing through an end point of the at least one of the four sides;
wherein the plurality of bumps are arranged in rows in a transverse direction, and are arranged in columns in a longitudinal direction, and wherein the plurality of bumps in rows in the transverse direction are disposed in a staggered manner, and the plurality of bumps in columns in the longitudinal direction are disposed in a staggered manner.

2. The chip structure of claim 1, wherein the chip substrate is bonded to the external connecting portion by an electrically conductive film, a shifting distance is formed between the chip substrate and the external connecting portion, and wherein the plurality of bumps in each row are in alignment with each other in the transverse direction, and a pitch is formed between the bumps adjacent to each other in the same row in the transverse direction and the pitch is greater than or equal to the shifting distance.

3. The chip structure of claim 1, wherein the surface of the chip substrate is rectangular in shape and has a first side and a second side perpendicular to the first side, and wherein each of the plurality of bumps having the rhombic configuration comprises a first corner connecting line perpendicular to the first side, and a second corner connecting line perpendicular to the first corner connecting line and the second side.

4. A chip structure, comprising:
a chip substrate; and
a plurality of bumps disposed on a surface of the chip substrate and functioning as an interface for electrical connection between the chip substrate and an external connecting portion, wherein the plurality of bumps are spaced apart from each other, and each of the plurality of bumps comprises a rhombic configuration.

5. The chip structure of claim 4, wherein each of the plurality of bumps has four sides of equal length, and at least one of the four sides is disposed at an angle of 45 degrees with respect to a horizontal line passing through an end point of the at least one of the four sides.

6. The chip structure of claim 4, wherein the plurality of bumps are arranged in rows in a transverse direction, and are arranged in columns in a longitudinal direction, and wherein the plurality of bumps in rows in the transverse direction are disposed in a staggered manner, and the plurality of bumps in columns in the longitudinal direction are disposed in a staggered manner.

7. The chip structure of claim 6, wherein each of the plurality of bumps in rows in the transverse direction is arranged at an equal pitch, and each of the plurality of bumps in columns in the longitudinal direction is arranged at an equal pitch.

8. The chip structure of claim 4, wherein the chip substrate is bonded to the external connecting portion by an electrically conductive film, a shifting distance is formed between the chip substrate and the external connecting portion, and wherein the plurality of bumps in each row are in alignment with each other in the transverse direction, and a pitch is formed between the bumps adjacent to each other in the same row in the transverse direction and the pitch is greater than or equal to the shifting distance.

9. The chip structure of claim 4, wherein the surface of the chip substrate is rectangular in shape and has a first side and a second side perpendicular to the first side, and wherein each of the plurality of bumps having the rhombic configuration comprises a first corner connecting line perpendicular to the first side, and a second corner connecting line perpendicular to the first corner connecting line and the second side.

10. A display device, comprising an organic light emitting display panel, a bonding area, and a chip structure disposed on the bonding area, wherein the chip structure comprises:
a chip substrate; and
a plurality of bumps disposed on a surface of the chip substrate and functioning as an interface for electrical connection between the chip substrate and an external connecting portion, wherein the plurality of bumps are spaced apart from each other, and each of the plurality of bumps comprises a rhombic configuration.

11. The display device of claim 10, wherein each of the plurality of bumps has four sides of equal length, and at least one of the four sides is disposed at an angle of 45 degrees with respect to a horizontal line passing through an end point of the at least one of the four sides.

12. The display device of claim 10, wherein the plurality of bumps are arranged in rows in a transverse direction, and are arranged in columns in a longitudinal direction, and wherein the plurality of bumps in rows in the transverse direction are disposed in a staggered manner, and the plurality of bumps in columns in the longitudinal direction are disposed in a staggered manner.

13. The display device of claim 10, wherein the chip substrate is bonded to the bonding area by an electrically conductive film, a shifting distance is formed between the chip substrate and the external connecting portion, and wherein the plurality of bumps in each row are in alignment with each other in the transverse direction, and a pitch is formed between the bumps adjacent to each other in the same row in the transverse direction and the pitch is greater than or equal to the shifting distance.
